(19) United States
(12) Patent Application Publication
(10) Pub. No.: US 2026/0175565 A1
(43) Pub. Date: Jun. 25, 2026

(54) Semiconductor Device

(71) Applicant: SEIKO EPSON CORPORATION, Tokyo (JP)

(72) Inventor: Satoru IMAI, Minamimaki (JP)

(21) Appl. No.: 19/431,051

(22) Filed: Dec. 23, 2025

(30) Foreign Application Priority Data
Dec. 25, 2024 (JP) 2024-229398

(51) Int. Cl. B41J 2/045; H10W 70/655; H10W 90/00

(52) U.S. Cl. CPC B41J 2/0452; B41J 2/04573; H10W 70/655; H10W 90/734; H10W 90/754

(57) ABSTRACT

A semiconductor device includes a package and an integrated circuit chip that is mounted on an internal substrate of the package. The integrated circuit chip includes a plurality of terminals, a control section, and a plurality of functional circuits; the internal substrate is provided with a first wiring that is coupled to a first terminal among the plurality of terminals and a second wiring that is coupled to a second terminal among the plurality of terminals; and the control section determines a type of the package based on a potential of the first terminal and a potential of the second terminal, and controls operations of the plurality of functional circuits according to the type of the package.

The present application is based on, and claims priority from JP Application Serial Number 2024-229398, filed December 25, 2024, the disclosure of which is hereby incorporated by reference herein in its entirety.

### BACKGROUND

### 1. Technical Field

The present disclosure relates to a semiconductor device.

### 2. Related Art

A semiconductor device is used in most current electronic products. Since a semiconductor device is used for numerous electronic products, a demand for miniaturization, multifunctionality, and low cost of the semiconductor device is increasing. In recent years, in order for human beings to stably continue to live on the earth, it is also required to take care of human society and the global environment with respect to electronic products. At the United Nations Summit held at the United Nations Headquarters in New York on September 25, 2015, the "2030 Agenda for Sustainable Development" with the "Sustainable Development Goals" (SDGs) at the core was adopted, and thereafter, various efforts have been made by the governments and companies of each country to achieve the goals.

For example, JP-A-2023-45901 discloses a semiconductor device in which a semiconductor element is mounted on a substrate for a semiconductor device, and it is expected that the semiconductor device contributes to the achievement of Goal 9 and Goal 12 of the Sustainable Development Goals (SDGs) proposed by the United Nations by simplifying the structure of a mounting pad body portion and an external electrode body portion, and providing the substrate for the semiconductor device, which includes the mounting pad body portion and the external electrode body portion insensitive to magnetism, at a lower cost.

The structural design of the semiconductor device and the production thereof are related to Goals 7, 8, 9, 11, and 12 of SDGs. Specifically, the structural design of the semiconductor device and the production thereof are related to the following goals.

Goal 7: Ensure access to affordable, reliable, and modern energy for all.

Goal 8: Facilitate more efficient use of resources globally in terms of consumption and production.

Goal 9: Ensure more efficient use of resources, incorporate more environmentally friendly technologies and production methods, and promote sustainable infrastructure and industry.

Goal 11: Reduce the environmental impact of an urban resident (per capita) by focusing on air quality, waste management, and related measures.

Goal 12: Sustainably manage natural resources and use the natural resources efficiently.

As described above, recent semiconductor devices are required not only to achieve miniaturization, multifunctionality, and cost reduction but also to contribute to the SDGs goals through their structural design and production methods therefor. Therefore, a semiconductor device that solves the various problems described above is desired.

### SUMMARY

According to an aspect of the present disclosure, there is provided a semiconductor device including a package, and an integrated circuit chip that is mounted on an internal substrate of the package, in which the integrated circuit chip includes a plurality of terminals, a control section, and a plurality of functional circuits, the internal substrate is provided with a first wiring that is coupled to a first terminal among the plurality of terminals and a second wiring that is coupled to a second terminal among the plurality of terminals, and the control section determines a type of the package based on a potential of the first terminal and a potential of the second terminal, and controls operations of the plurality of functional circuits according to the type of the package.

### BRIEF DESCRIPTION OF THE DRAWINGS

FIG. 1 is an external perspective view of an electronic apparatus.

FIG. 2 is a diagram showing an example of a functional configuration of the electronic apparatus.

FIG. 3 is a cross-sectional view showing a structure of a semiconductor device.

FIG. 4 is a transparent view of a terminal mounting surface of a package.

FIG. 5 is a transparent view of a terminal mounting surface of a package.

FIG. 6 is a functional block diagram of an integrated circuit chip.

FIG. 7 is a diagram showing an example of a correspondence relationship between potentials of terminals of an integrated circuit chip and packages.

FIG. 8 is a plan view of a part of a printed circuit board.

FIG. 9 is a plan view of a part of a printed circuit board.

FIG. 10 is a diagram showing the semiconductor device mounted on the printed circuit board.

FIG. 11 is a diagram showing the semiconductor device mounted on the printed circuit board.

FIG. 12 is a diagram showing an example of a correspondence relationship between modes of a control section and signals propagating to terminals of a semiconductor device.

### DESCRIPTION OF EMBODIMENTS

Hereinafter, preferred embodiments of the present disclosure will be described with reference to the drawings. The drawings to be used are for convenience of description. Further, the embodiments to be described below do not inappropriately limit the contents of the present disclosure described in the claims. Furthermore, not all configurations to be described below are necessarily essential components of the present disclosure.

Hereinafter, an electronic apparatus according to an embodiment will be described using a multifunction apparatus including a printing function and a scanning function as an example of an electronic apparatus according to the present disclosure.

### 1. Structure of Electronic Apparatus

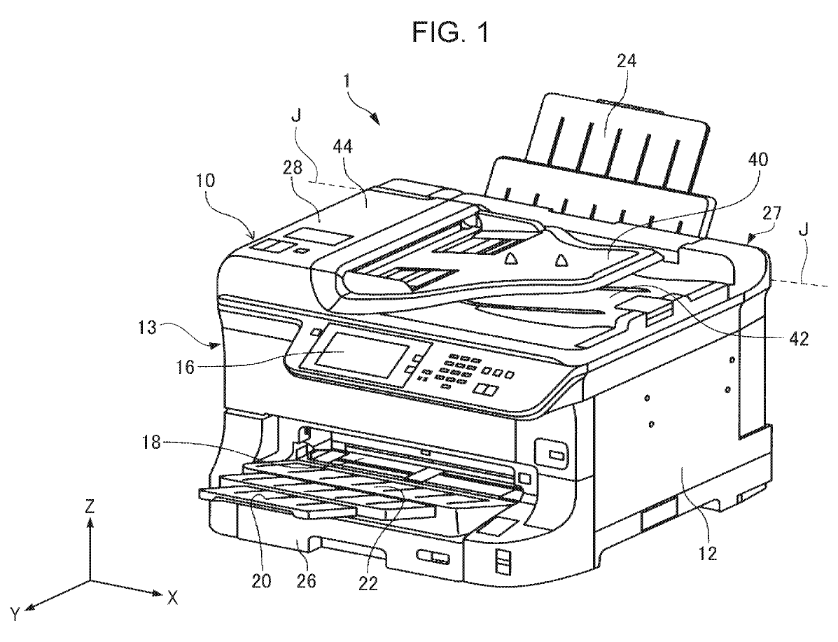

FIG. 1 is an external perspective view of an electronic apparatus 1. In the following, description will be made using an X direction, a Y direction, and a Z direction orthogonal to each other. Further, a starting point side of an arrow indicating the X direction may be referred to as a -X side and a tip side of the arrow may be referred to as a +X side; a starting point side of an arrow indicating the Y direction may be referred to as a -Y side and a tip side of the arrow may be referred to as a +Y side; and a starting point side of an arrow indicating the Z direction may be referred to as a -Z side and a tip side of the arrow may be referred to as a +Z side.

The electronic apparatus 1 includes an apparatus body 12 that has a substantially rectangular parallelepiped shape as a whole. The apparatus body 12 includes: a recording device 13 that performs recording on a sheet; and an image reading device 10 that is provided on the recording device 13 and reads information, such as pictures, text, and photographs, formed on a document placed thereon to generate an image. For example, the image generated by the image reading device 10 is printed on a sheet by the recording device 13.

The image reading device 10 includes an auto document feeder (ADF) 27 that is an automatic document feeding unit. The ADF 27 is provided to be rotatable about a rear side, which is the -Y side, of the apparatus body 12 as a fulcrum of a rotation axis J, and also has a function of a top plate that can be opened and closed with respect to an upper portion of the apparatus body 12.

The ADF 27 includes a document transport section 28 that includes a drive mechanism for transporting documents, a document placement surface 40, and a document discharge surface 42. A document placed on the document placement surface 40 is fed into the image reading device 10 by the document transport section 28, read, and then discharged, and is placed on the document discharge surface 42.

An operation section 16 is provided at an upper portion of a front side, which is to the +Y side, of the apparatus body 12 and the operation section 16 includes a power button and print setting buttons for operating the electronic apparatus 1, a display panel, and the like.

A rear tray 24 on which sheets are to be placed is provided on the rear side, which is the -Y side, of the apparatus body 12. Sheets placed on the rear tray 24 are fed to the recording device 13 and are subjected to recording.

A sheet storage section 26 in which a plurality of sheets are stored is provided on a bottom side, which is the -Z side, of a front tray 22. The sheet storage section 26 is provided at a lower portion of the apparatus body 12 to be slidable in the Y direction, and is configured to be attachable to and detachable from the apparatus body 12. The sheets placed in the sheet storage section 26 are fed to the recording device 13 and are subjected to recording.

A pull-out section 20, which is attached to the front tray 22 and slidable in the Y direction, is provided on the front side of the apparatus body 12. The sheet, which is fed from the rear tray 24 or the sheet storage section 26 to the recording device 13 and is subjected to recording, is discharged from an opening portion 18 provided on the front side of the apparatus body 12, and is placed on the front tray 22 and the pull-out section 20 pulled out of the front tray 22.

### 2. Functional Configuration of Electronic Apparatus

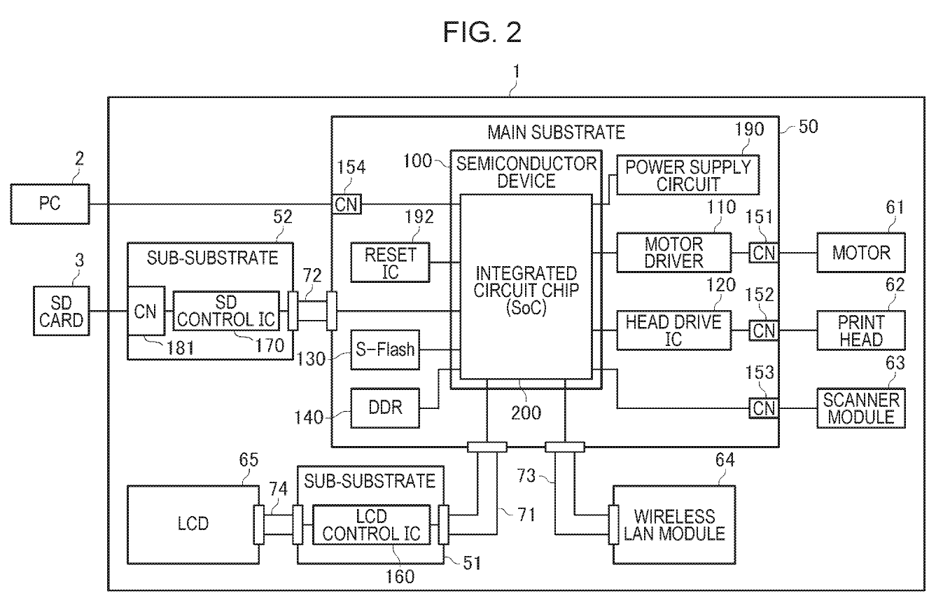

FIG. 2 is a diagram showing an example of a functional configuration of the electronic apparatus 1. As shown in FIG. 2, the electronic apparatus 1 includes a main substrate 50, a sub-substrate 51, and a sub-substrate 52. The main substrate 50 and the sub-substrates 51 and 52 are, for example, multilayer printed circuit boards.

A semiconductor device 100 including an integrated circuit chip 200, a motor driver 110, a head drive IC 120, a serial flash memory 130, a DDR 140, a power supply circuit 190, and a reset IC 192 are mounted on the main substrate 50. DDR is an abbreviation for Double-Data-Rate SDRAM. Further, the main substrate 50 is provided with connectors 151, 152, 153, and 154.

An LCD control IC 160 is mounted on the sub-substrate 51. The sub-substrate 51 is coupled to the main substrate 50 by a cable 71.

An SD control IC 170 is mounted on the sub-substrate 52, and the sub-substrate 52 is provided with a connector 181. The sub-substrate 52 is coupled to the main substrate 50 by a cable 72.

Further, the electronic apparatus 1 includes various motors 61, a print head 62, a scanner module 63, a wireless LAN module 64, and an LCD 65. LAN is an abbreviation for Local Area Network. LCD is an abbreviation for Liquid Crystal Display.

The motor 61 is coupled to the main substrate 50 via the connector 151 and is driven by the motor driver 110.

The print head 62 is provided in the recording device 13, is coupled to the main substrate 50 via the connector 152, and is driven by the head drive IC 120.

The scanner module 63 is provided in the image reading device 10, is coupled to the main substrate 50 via the connector 153, and is controlled by the integrated circuit chip 200. Further, the scanner module 63 transmits scan data, which is generated through the scanning of the document, to the integrated circuit chip 200.

The wireless LAN module 64 is a module that performs wireless data communication with an external device of the electronic apparatus 1. The wireless LAN module 64 is coupled to the main substrate 50 via a cable 73 and is controlled by the integrated circuit chip 200. The wireless LAN module 64 performs USB communication with the integrated circuit chip 200.

The LCD 65 is a display panel that is included in the operation section 16 and displays various types of information. The LCD 65 is coupled to the sub-substrate 51 via a cable 74 and is controlled by the LCD control IC 160.

The LCD control IC 160 is a circuit that is coupled to the LCD 65 via the cable 74 and controls the display of various types of information on the LCD 65. The LCD control IC 160 is controlled by the integrated circuit chip 200.

The SD control IC 170 is a circuit that controls writing and reading of data to and from an SD card 3 inserted into the connector 181. The SD control IC 170 is controlled by the integrated circuit chip 200. The SD control IC 170 performs USB communication with the integrated circuit chip 200.

The motor driver 110 is a circuit that is coupled to the motor 61 via the connector 151 and drives the motor 61. The motor driver 110 is controlled by the integrated circuit chip 200.

The head drive IC 120 is a circuit that is coupled to the print head 62 via the connector 152 and drives the print head 62. The head drive IC 120 is controlled by the integrated circuit chip 200.

Each of the serial flash memory 130 and the DDR 140 is a storage device that stores various types of data, and the writing and reading of data thereto and therefrom are controlled by the integrated circuit chip 200.

The power supply circuit 190 supplies power to the semiconductor device 100, the motor driver 110, the head drive IC 120, the serial flash memory 130, and the DDR 140. For example, the power supply circuit 190 generates a power supply voltage of several V and supplies the power supply voltage to the semiconductor device 100, the motor driver 110, the head drive IC 120, the serial flash memory 130, and the DDR 140. Further, the power supply circuit 190 generates a power supply voltage of several tens of V for driving the motor 61 and the print head 62, and supplies the power supply voltage to the motor driver 110 and the head drive IC 120. The power supply circuit 190 is controlled by the integrated circuit chip 200.

The reset IC 192 resets the semiconductor device 100 when the reset IC 192 monitors a power supply voltage of the semiconductor device 100 and determines that the power supply voltage is abnormal. The reset IC 192 is controlled by the integrated circuit chip 200.

As described above, the integrated circuit chip 200 is an SoC that controls the motor driver 110, the head drive IC 120, the serial flash memory 130, the DDR 140, the scanner module 63, the wireless LAN module 64, the LCD control IC 160, the SD control IC 170, the power supply circuit 190, and the reset IC 192. SoC is an abbreviation for System On Chip.

Further, the integrated circuit chip 200 is coupled to a PC 2 provided outside the electronic apparatus 1 via the connector 154, and performs data communication with the PC 2. The connector 154 is, for example, a USB connector.

### 3. Structure of Semiconductor Device

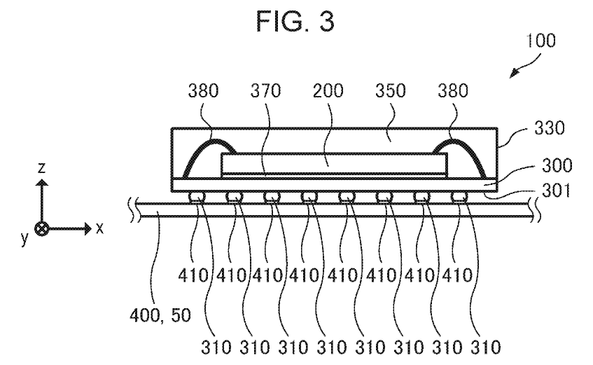

FIG. 3 is a cross-sectional view showing a structure of the semiconductor device 100. In the following, description will be made using an x direction, a y direction, and a z direction that are directions independent of the X direction, the Y direction, and the Z direction shown in FIG. 1 and orthogonal to each other. Further, a starting point side of an arrow indicating the x direction may be referred to as a -x side and a tip side of the arrow may be referred to as a +x side; a starting point side of an arrow indicating the y direction may be referred to as a -y side and a tip side of the arrow may be referred to as a +y side; and a starting point side of an arrow indicating the z direction may be referred to as a -z side and a tip side of the arrow may be referred to as a +z side.

As shown in FIG. 3, the semiconductor device 100 includes a base substrate 300, the integrated circuit chip 200, and a housing 350.

The housing 350 is positioned on the +z side of the integrated circuit chip 200 and is bonded to the base substrate 300 to cover the integrated circuit chip 200. The housing 350 contains an epoxy resin and the like and protects the integrated circuit chip 200.

The base substrate 300 is located on the -z side of the integrated circuit chip 200. The integrated circuit chip 200 is mounted on the base substrate 300 by a bonding member 370 such as an adhesive. The base substrate 300 and the integrated circuit chip 200 are electrically coupled to each other via bonding wires 380.

The base substrate 300 is provided with a plurality of wiring patterns and a plurality of electrodes (not shown). The bonding wires 380 are electrically coupled to electrodes (not shown) formed on the surface of the base substrate 300 facing the +z side. Further, the plurality of electrodes (not shown) are provided on the surface of the base substrate 300 facing the -z side. A solder ball 310 is attached to each of the plurality of electrodes provided on the surface of the base substrate 300 facing the -z side. That is, the base substrate 300 is provided with a plurality of solder balls 310 that are a plurality of ball-shaped terminals. The printed circuit board 400, which is the main substrate 50 shown in FIG. 2, is provided with a plurality of pads 410 and a plurality of wirings (not shown), and each of the plurality of solder balls 310 and each of the plurality of pads 410 are bonded to each other. The base substrate 300 is electrically coupled to the printed circuit board 400 by the plurality of solder balls 310. The plurality of solder balls 310 form a so-called ball grid array that electrically and mechanically connects the base substrate 300 and the printed circuit board 400. In the following description, the surface of the base substrate 300 which faces the -z side and to which the plurality of solder balls 310 are attached is referred to as a terminal mounting surface 301.

A package 330 is formed of a ball grid array that includes the base substrate 300, the housing 350, and the plurality of solder balls 310. The integrated circuit chip 200 is mounted on the base substrate 300 that is an internal substrate of the package 330.

In the semiconductor device 100 having the configuration described above, signals input to the semiconductor device 100 via the plurality of solder balls 310 provided on the terminal mounting surface 301 propagate via the electrodes and the wiring patterns provided on the base substrate 300 and the bonding wires 380, and are input to the integrated circuit chip 200. Further, signals output from the integrated circuit chip 200 are input to the plurality of pads 410 of the printed circuit board 400 via the bonding wires 380, the electrodes and the wiring patterns provided on the base substrate 300, and the plurality of solder balls 310.

In the present embodiment, the integrated circuit chip 200 can be mounted in a plurality of types of packages 330. In the following, the integrated circuit chip 200 will be described as an integrated circuit chip to be mounted in any one of the four types of packages, such as packages 330a, 330b, 330c, and 330d, but the type of the package 330 in which the integrated circuit chip 200 is mounted is not limited to the four types. When the package 330 will be described as any one of the packages 330a, 330b, 330c, and 330d in the following, "a", "b", "c", or "d" will also be added to the reference numerals of the components of the package.

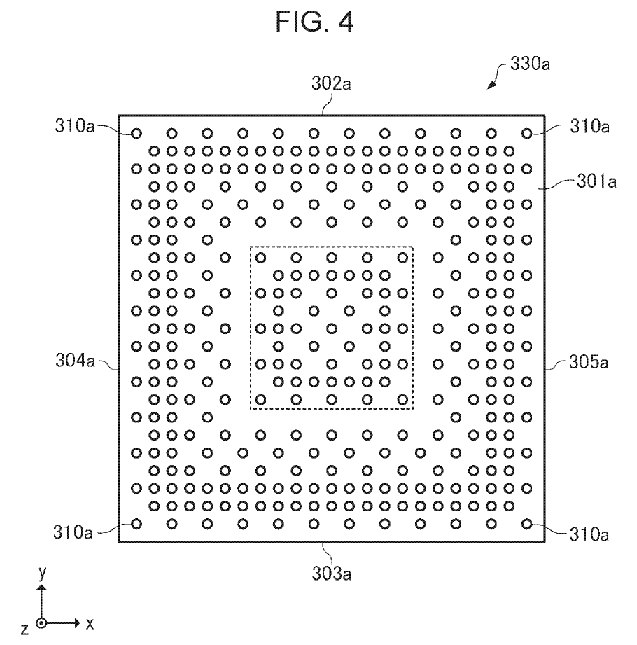

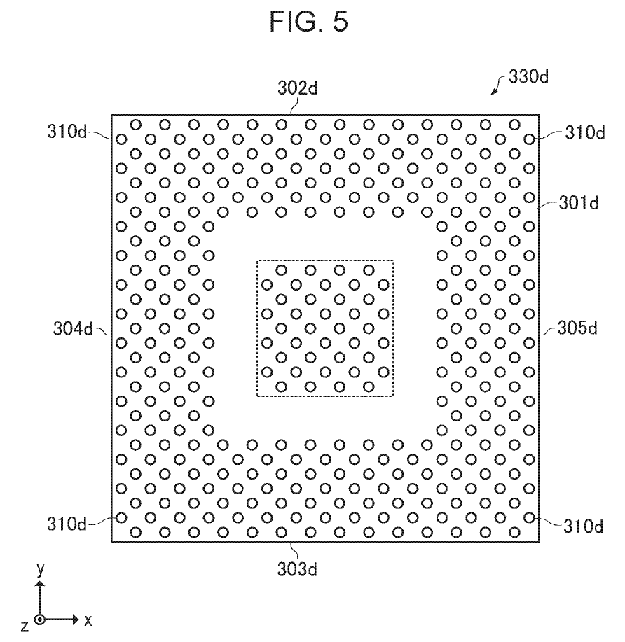

FIG. 4 is a transparent view of a terminal mounting surface 301a of a base substrate 300a of a package 330a as viewed from the +z side. Further, FIG. 5 is a transparent view of a terminal mounting surface 301d of a base substrate 300d of a package 330d as viewed from the +z side. The package 330a is a small-sized package and, for example, the terminal mounting surface 301a has a size of 12mm × 12mm. The package 330d is a large-sized package and, for example, the terminal mounting surface 301d has a size of 16mm × 16mm.

As shown in FIG. 4, the base substrate 300a of the package 330a includes a side 302a that extends in the x direction, a side 303a that extends in the x direction and faces the side 302a, a side 304a that extends in the y direction, and a side 305a that extends in the y direction and faces the side 304a. Each of the sides 304a and 305a intersects the sides 302a and 303a. That is, the base substrate 300a has a substantially rectangular shape having the sides 302a, 303a, 304a, and 305a on the outer periphery thereof.

As shown in FIG. 4, on the terminal mounting surface 301a of the base substrate 300a, a plurality of solder balls 310a are arranged in a grid shape to be dispersed in 23 rows in the y direction, and a maximum of 23 solder balls 310a are arranged in each row. The solder balls 310a to be coupled to the motor driver 110, the head drive IC 120, the serial flash memory 130, the DDR 140, the connectors 151, 152, 153, and 154, and the like are arranged at the outermost peripheral portion of the terminal mounting surface 301a and at positions close to the outermost peripheral portion. An interval between the plurality of solder balls 310a arranged at the outermost periphery is set to be wide so that a space through which wirings to be coupled to the solder balls 310a arranged on the inner side of the plurality of solder balls 310a pass is ensured. Further, the power supply voltage is supplied to the plurality of solder balls 310a arranged in a region that is near the center of the terminal mounting surface 301a and surrounded by a broken line.

As shown in FIG. 5, the base substrate 300d of the package 330d includes a side 302d that extends in the x direction, a side 303d that extends in the x direction and faces the side 302d, a side 304d that extends in the y direction, and a side 305d that extends in the y direction and faces the side 304d. Each of the sides 304d and 305d intersects the sides 302d and 303d. That is, the base substrate 300d has a substantially rectangular shape having the sides 302d, 303d, 304d, and 305d on the outer periphery thereof.

As shown in FIG. 5, on the terminal mounting surface 301d of the base substrate 300d, a plurality of solder balls 310d are arranged in a zigzag pattern to be dispersed in 29 rows in the y direction, and a maximum of 15 solder balls 310d are arranged in each row. The solder balls 310d to be coupled to the motor driver 110, the head drive IC 120, the serial flash memory 130, the DDR 140, the connectors 151, 152, 153, and 154, and the like are arranged at the outermost peripheral portion of the terminal mounting surface 301d and at positions close to the outermost peripheral portion. Further, the power supply voltage is supplied to the plurality of solder balls 310d arranged in a region that is near the center of the terminal mounting surface 301d and surrounded by a broken line.

### 4. Functional Configuration of Integrated Circuit Chip

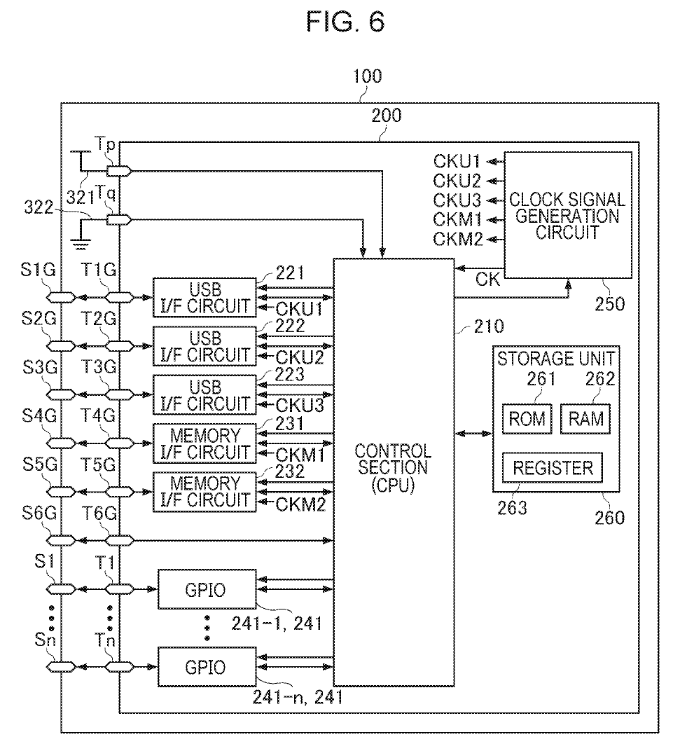

FIG. 6 is a functional block diagram of the integrated circuit chip 200. As shown in FIG. 6, the integrated circuit chip 200 includes a control section 210, USB interface circuits 221, 222, and 223, memory interface circuits 231 and 232, n GPIOs 241-1 to 241-n, a clock signal generation circuit 250, and a storage unit 260. GPIO is an abbreviation for General-Purpose Input/Output. The integrated circuit chip 200 may have a configuration in which a part of components shown in FIG. 6 are omitted or changed or other components are added.

The clock signal generation circuit 250 generates and outputs clock signals CKU1, CKU2, CKU3, CKM1, CKM2, and CK. For example, the clock signal generation circuit 250 may generate clock signals CKU1, CKU2, CKU3, CKM1, CKM2, and CK by dividing or multiplying a source oscillation signal obtained by oscillating a crystal oscillator (not shown) mounted on the base substrate 300. The clock signals CKU1, CKU2, and CKU3 are supplied to the USB interface circuits 221, 222, and 223, respectively. The clock signals CKM1 and CKM2 are supplied to the memory interface circuits 231 and 232, respectively. Further, the clock signal CK is supplied to the control section 210.

The USB interface circuit 221 is coupled to a terminal group T1G including a plurality of terminals of the integrated circuit chip 200. The USB interface circuit 222 is coupled to a terminal group T2G including a plurality of terminals of the integrated circuit chip 200. The USB interface circuit 223 is coupled to a terminal group T3G including a plurality of terminals of the integrated circuit chip 200. The memory interface circuit 231 is coupled to a terminal group T4G including a plurality of terminals of the integrated circuit chip 200. The memory interface circuit 232 is coupled to a terminal group T5G including a plurality of terminals of the integrated circuit chip 200. The control section 210 is coupled to a terminal group T6G including a plurality of terminals of the integrated circuit chip 200.

The terminal groups T1G to T6G of the integrated circuit chips 200 are coupled to terminal groups S1G to S6G of the semiconductor device 100, respectively. Each of the terminals included in the terminal groups S1G to S6G of the semiconductor device 100 is the solder ball 310 provided on the terminal mounting surface 301. The terminal group S1G of the semiconductor device 100 is coupled to the PC 2 via the connector 154. The terminal group S2G of the semiconductor device 100 is coupled to the SD control IC 170 via the cable 72. The terminal group S3G of the semiconductor device 100 is coupled to the wireless LAN module 64 via the cable 73. The terminal group S4G of the semiconductor device 100 is coupled to the serial flash memory 130. The terminal group S5G of the semiconductor device 100 is coupled to the DDR 140. The terminal group S6G of the semiconductor device 100 is coupled to the LCD control IC 160.

The GPIOs241-1 to 241-n are coupled to terminals T1 to Tn of the integrated circuit chip 200, respectively. The terminals T1 to Tn of the integrated circuit chip 200 are coupled to terminals S1 to Sn of the semiconductor device 100, respectively. The terminals S1 to Sn of the semiconductor device 100 are the solder balls 310 provided on the terminal mounting surface 301. Terminals Tp and Tq of the integrated circuit chip 200 are coupled to wirings 321 and 322 provided on the base substrate 300 of the package 330, respectively. In the base substrate 300, the wiring 321 is fixed to a power supply potential or a ground potential and the wiring 322 is fixed to the power supply potential or the ground potential. In FIG. 6, the wiring 321 is fixed to the power supply potential and the wiring 322 is fixed to the ground potential.

The storage unit 260 includes a ROM 261, a RAM 262, and a register 263. ROM is an abbreviation for Read Only Memory, and RAM is an abbreviation for Random Access Memory. The ROM 261 stores various programs and predetermined data. The RAM 262 is used as a work area for the control section 210, and stores a program or data read from the ROM 261 and data temporarily generated by the control section 210. The register 263 stores various setting data and the like.

The control section 210 performs various controls, image processing, and the like. In the present embodiment, the control section 210 is a processor such as a CPU, and performs various controls, image processing, and the like by executing a program (not shown) stored in the ROM 261. However, a part of the processing of the control section 210 may be realized by hardware.

Specifically, the control section 210 performs various controls on the motor driver 110, the head drive IC 120, the scanner module 63, and the LCD control IC 160.

Further, the control section 210 controls the USB interface circuit 221 to perform USB communication with the PC 2. Furthermore, the control section 210 controls the USB interface circuit 222 to perform USB communication with the SD control IC 170. Moreover, the control section 210 controls the USB interface circuit 223 to perform USB communication with the wireless LAN module 64. In addition, the control section 210 transmits image data to the LCD control IC 160.

Further, the control section 210 controls the memory interface circuit 231 to write and read data to and from the serial flash memory 130. Furthermore, the control section 210 controls the memory interface circuit 232 to write and read data to and from the DDR 140.

For example, the control section 210 receives image data for printing from the PC 2 via the USB interface circuit 221 and writes the image data to the serial flash memory 130 or the DDR 140. Further, for example, the control section 210 receives image data stored in the SD card 3 from the SD control IC 170 via the USB interface circuit 222 and writes the image data to the serial flash memory 130 or the DDR 140. Furthermore, for example, the control section 210 receives image data from the wireless LAN module 64 via the USB interface circuit 223 and writes the image data to the serial flash memory 130 or the DDR 140. Moreover, for example, the control section 210 acquires scan data from the scanner module 63, performs image processing on the scan data to generate image data, and writes the image data to the serial flash memory 130 or the DDR 140.

Further, for example, the control section 210 writes the image data, which is generated by performing the image processing on the scan data, to the serial flash memory 130 or the DDR 140.

Furthermore, for example, the control section 210 reads image data for printing from the serial flash memory 130 or the DDR 140, performs image processing for printing on the image data to generate print data, and outputs the print data to the head drive IC 120. Moreover, for example, the control section 210 reads image data from the serial flash memory 130 or the DDR 140 and transmits the image data to the PC 2 via the USB interface circuit 221. In addition, for example, the control section 210 reads image data from the serial flash memory 130 or the DDR 140 and transmits the image data to the SD control IC 170 via the USB interface circuit 222. Further, for example, the control section 210 reads image data from the serial flash memory 130 or the DDR 140 and transmits the image data to the wireless LAN module 64 via the USB interface circuit 223.

Furthermore, the control section 210 controls the input and output of each of the GPIOs241-1 to 241-n. Specifically, the control section 210 controls each of the GPIOs 241-1 to 241-n to be any of an input/output circuit, an input circuit, and an output circuit. For example, the control section 210 may control a GPIO 241-k among the GPIOs 241-1 to 241-n and a terminal Tl to be output circuits, and may output control signals to the power supply circuit 190 and the reset IC 192 from the terminals Tk and Tl, respectively.

Further, potentials of the terminals Tp and Tq are supplied to the control section 210 in the present embodiment. Then, the control section 210 determines the type of the package 330 in which the integrated circuit chip 200 is mounted, based on the potentials of the terminals Tp and Tq. That is, the control section 210 determines whether the package 330 is any of the packages 330a, 330b, 330c, and 330d based on the potentials of the terminals Tp and Tq.

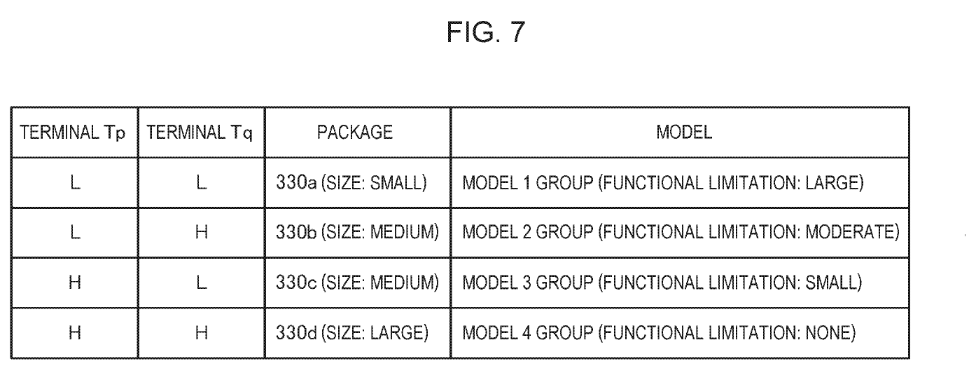

FIG. 7 is a diagram showing an example of a correspondence relationship between the potentials of the terminals Tp and Tq and the packages 330a, 330b, 330c, and 330d. In the example shown in FIG. 7, the control section 210 determines that the package 330 is the package 330a when both the potentials of the terminals Tp and Tq are at a low level. The package 330a is a small-sized package, and the electronic apparatus 1 in which the semiconductor device 100 is mounted belongs to a model 1 group with large functional limitations.

Further, the control section 210 determines that the package 330 is the package 330b when the potential of the terminal Tp is at a low level and the potential of the terminal Tq is at a high level. The package 330b is a medium-sized package, and the electronic apparatus 1 in which the semiconductor device 100 is mounted belongs to a model 2 group with moderate functional limitations.

Furthermore, the control section 210 determines that the package 330 is the package 330c when the potential of the terminal Tp is at a high level and the potential of the terminal Tq is at a low level. The package 330c is a medium-sized package, and the electronic apparatus 1 in which the semiconductor device 100 is mounted belongs to a model 3 group with small functional limitations.

Moreover, the control section 210 determines that the package 330 is the package 330d when both the potentials of the terminals Tp and Tq are at a high level. The package 330d is a large-sized package, and the electronic apparatus 1 in which the semiconductor device 100 is mounted belongs to a model 4 group with no functional limitation.

As described above, the size of the package is increased in the order of the packages 330d, 330c, 330b, and 330a, and the functional limitations of the electronic apparatus 1 in which the semiconductor device 100 is mounted are increased in the order of the packages 330a, 330b, 330c, and 330d. Therefore, the control section 210 controls the operation of each functional circuit, such as the USB interface circuits 221, 222, and 223, the memory interface circuits 231 and 232, and the GPIOs241-1 to 241-n, according to the type of the package 330.

For example, the control section 210 may determine whether a predetermined terminal Ti of the integrated circuit chip 200 is also used as a CMOS terminal or an LVDS terminal, according to the type of the package 330. CMOS is an abbreviation for Complementary Metal Oxide Semiconductor. LVDS is an abbreviation for Low Voltage Differential Signaling. For example, the control section 210 determines that the terminal Ti is dedicated as the CMOS terminal or the LVDS terminal when the package 330 is the package 330a, and determines that the terminal Ti is also used as the CMOS terminal or the LVDS terminal when the package 330 is the package 330d.

Further, the control section 210 may fix the potential of each unused terminal Tj among the plurality of terminals of the integrated circuit chip 200 to a low level, according to the type of the package 330. For example, when a terminal T2 is not used, the control section 210 controls the GPIO 241-2 to be an output circuit and controls the terminal T2 to have a low level potential. In this case, since each unused terminal Tj assumes an intermediate potential, a possibility that an element such as a MOSFET provided in the integrated circuit chip 200 is damaged due to a through-current flowing through the element is reduced and a possibility that the integrated circuit chip 200 malfunctions due to noise is reduced. Further, since a possibility that each terminal Sj of the semiconductor device 100 coupled to each unused terminal Tj assumes an intermediate potential is reduced, a possibility that an external device coupled to each terminal Sj malfunctions is reduced.

Further, the control section 210 may stop supplying clock signals to unused functional circuits according to the type of the package 330. For example, when the control section 210 determines that the package 330 is the package 330a, the control section 210 controls the clock signal generation circuit 250 and stops supplying the clock signals CKU2 and CKU3 to the USB interface circuits 222 and 223 when the functions of the SD card 3 and the wireless LAN module 64 are unnecessary. Since power consumption is reduced in this case, a rise in the internal temperature of the small package 330a having a poor heat dissipation property is suppressed. As a result, a possibility that the semiconductor device 100 malfunctions is reduced.

Further, the control section 210 may stop supplying power to unused functional circuits according to the type of the package 330. For example, when the control section 210 determines that the package 330 is the package 330a, the control section 210 stops supplying power to the USB interface circuits 222 and 223 when the functions of the SD card 3 and the wireless LAN module 64 are unnecessary. Since power consumption is reduced in this case, a rise in the internal temperature of the small package 330a having a poor heat dissipation property is suppressed. As a result, a possibility that the semiconductor device 100 malfunctions is reduced.

The control section 210 may stop supplying clock signals to unused functional circuits and may stop supplying power according to the type of the package 330.

Further, the control section 210 may not perform initial settings for the unused functional circuits according to the type of the package 330. For example, when the control section 210 determines that the package 330 is the package 330a, the control section 210 does not perform initial settings for the USB interface circuits 222 and 223 when the functions of the SD card 3 and the wireless LAN module 64 are unnecessary. Since unnecessary initial settings are not required in this case, the startup time of the semiconductor device 100 is shortened.

Further, the control section 210 may change the frequency of the clock signal CK according to the type of the package 330. For example, when the control section 210 determines that the package 330 is the package 330d, the control section 210 controls the clock signal generation circuit 250 such that the frequency of the clock signal CK is included in a first frequency range. Furthermore, when the control section 210 determines that the package 330 is the package 330c, the control section 210 controls the clock signal generation circuit 250 such that the frequency of the clock signal CK is included in a second frequency range lower than the first frequency range. Moreover, when the control section 210 determines that the package 330 is the package 330b, the control section 210 controls the clock signal generation circuit 250 such that the frequency of the clock signal CK is included in a third frequency range lower than the second frequency range. Further, when the control section 210 determines that the package 330 is the package 330a, the control section 210 controls the clock signal generation circuit 250 such that the frequency of the clock signal CK is included in a fourth frequency range lower than the third frequency range. In this case, the larger the size of the package 330 is, the better the heat dissipation property of the package 330 is. Accordingly, the control section 210 can improve the performance of the semiconductor device 100 by increasing the frequency range of the clock signal CK. Furthermore, the smaller the size of the package 330 is, the worse the heat dissipation property of the package 330 is. Accordingly, the control section 210 can reduce power consumption by reducing the maximum frequency of the clock signal CK. For this reason, a rise in the internal temperature of the package 330 is suppressed. As a result, a possibility that the semiconductor device 100 malfunctions is reduced.

### 5. Switching of Terminal Functions of Semiconductor Device

In the present embodiment, the semiconductor device 100 can be mounted on a plurality of types of printed circuit boards 400. The semiconductor device 100 will be described as being mountable on any of two types of printed circuit boards 400A and 400B in the following, but the type of the printed circuit board 400 on which the semiconductor device 100 is mounted is not limited to two types. The printed circuit boards 400A and 400B correspond to the main substrate 50 shown in FIG. 2.

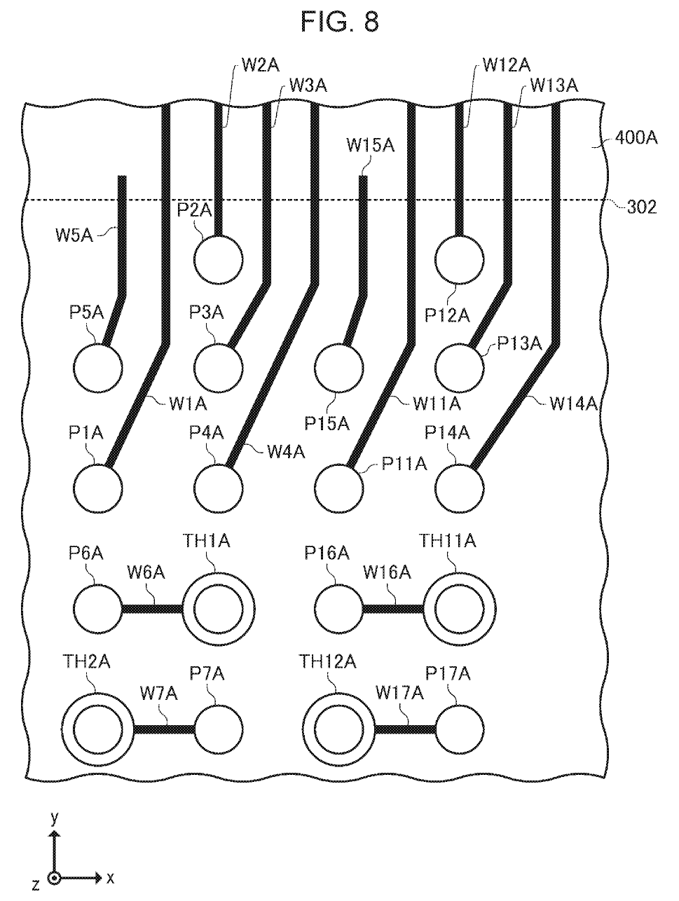

FIG. 8 is a plan view of a part of the printed circuit board 400A as viewed from the +z side. The printed circuit board 400A is provided with a plurality of pads 410 as shown in FIG. 3, and the plurality of pads 410 include pads P1A, P2A, P3A, P4A, P5A, P6A, P7A, P11A, P12A, P13A, P14A, P15A, P16A, and P17A as shown in FIG. 8. Each of the plurality of pads 410 is provided at a position corresponding to each of the plurality of solder balls 310 which are the plurality of terminals of the semiconductor device 100 and each solder ball 310 is bonded to each pad 410, so that the semiconductor device 100 is mounted on the printed circuit board 400A. In FIG. 8, a side 302 of the terminal mounting surface 301 is shown by a broken line. That is, each of the pads P2A and P12A is bonded to the outermost peripheral solder ball 310 provided on the terminal mounting surface 301.

Then, as the semiconductor device 100 is mounted on the printed circuit board 400A, each of the plurality of pads 410 provided on the printed circuit board 400A is electrically coupled to any one of the terminals of the semiconductor device 100 and any one of the terminals of the integrated circuit chip 200.

The printed circuit board 400A is provided with a plurality of wirings including wirings W1A, W2A, W3A, W4A, W5A, W6A, W7A, W11A, W12A, W13A, W14A, W15A, W16A, and W17A. Further, the printed circuit board 400A is a multilayer substrate, and is provided with a plurality of through-holes including through-holes TH1A, TH2A, TH11A, and TH12A.

The wirings W1A, W2A, W3A, W4A, W5A, W6A, and W7A are coupled to the pads P1A, P2A, P3A, P4A, P5A, P6A, and P7A, respectively. Furthermore, the wirings W11A, W12A, W13A, W14A, W15A, W16A, and W17A are coupled to the pads P11A, P12A, P13A, P14A, P15A, P16A, and P17A, respectively. The wiring W6A is coupled to a wiring (not shown) provided on another layer through the through-hole TH1A. The wiring W7A is coupled to a wiring (not shown) provided on another layer through the through-hole TH2A. The wiring W16A is coupled to a wiring (not shown) provided on another layer through the through-hole TH11A. The wiring W17A is coupled to a wiring (not shown) provided on another layer through the through-hole TH12A.

The wiring W5A extends from the pad P5A in the y direction. The wiring W1A extends from the pad P1A in the y direction through a space between the pad P5A and the pad P3A. The wiring W4A extends from the pad P4A in the y direction through a space between the pad P3A and the pad P15A. The wiring W2A extends from the pad P2A in the y direction through a space between the wiring W1A and the wiring W3A. The wiring W3A extends from the pad P3A in the y direction through a space between the wiring W2A and the wiring W4A. That is, the wirings W2A and W3A are positioned between the wiring W1A and the wiring W4A.

The wiring W15A extends from the pad P15A in the y direction through a space between the wiring W4A and the wiring W11A. The wiring W11A extends from the pad P11A in the y direction through a space between the pad P15A and the pad P13A. The wiring W14A extends from the pad P14A in the y direction. The wiring W12A extends from the pad P12A in the y direction through a space between the wiring W11A and the wiring W13A. The wiring W13A extends from the pad P13A in the y direction through a space between the wiring W12A and the wiring W14A. That is, the wirings W12A and W13A are positioned between the wiring W11A and the wiring W14A.

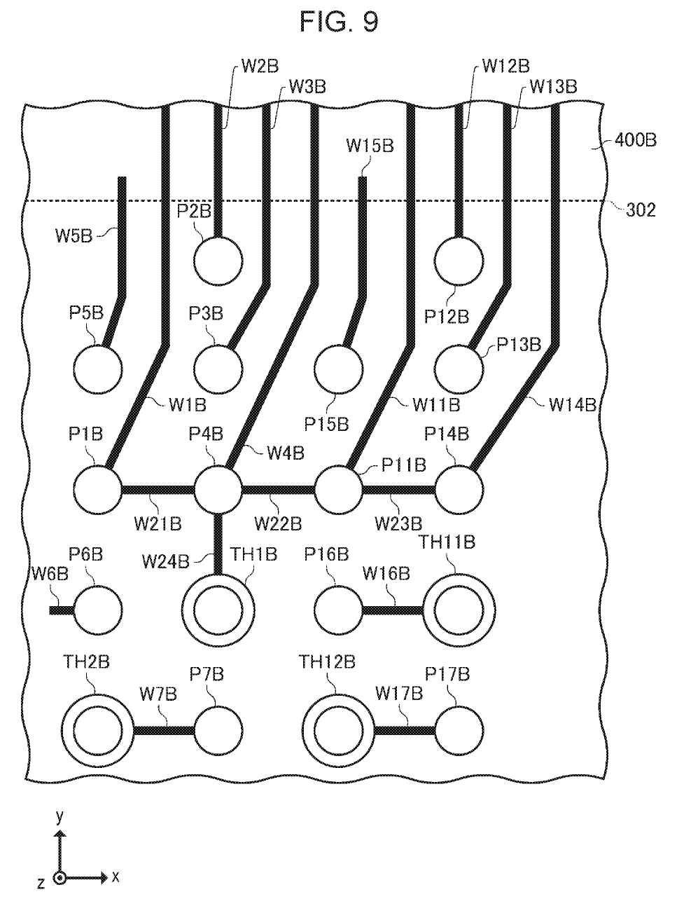

FIG. 9 is a plan view of a part of the printed circuit board 400B as viewed from the +z side. As shown in FIG. 9, a plurality of pads 410 provided on the printed circuit board 400B include pads P1B, P2B, P3B, P4B, P5B, P6B, P7B, P11B, P12B, P13B, P14B, P15B, P16B, and P17B. Each of the plurality of pads 410 is provided at a position corresponding to each of the plurality of solder balls 310 which are the plurality of terminals of the semiconductor device 100 and each solder ball 310 is bonded to each pad 410, so that the semiconductor device 100 is mounted on the printed circuit board 400B. In FIG. 9, the side 302 of the terminal mounting surface 301 is shown by a broken line. That is, each of the pads P2B and P12B is bonded to the outermost peripheral solder ball 310 provided on the terminal mounting surface 301.

Then, as the semiconductor device 100 is mounted on the printed circuit board 400B, each of the plurality of pads 410 provided on the printed circuit board 400B is electrically coupled to any one of the terminals of the semiconductor device 100 and any one of the terminals of the integrated circuit chip 200.

The printed circuit board 400B is provided with a plurality of wirings including wirings W1B, W2B, W3B, W4B, W5B, W6B, W7B, W11B, W12B, W13B, W14B, W15B, W16B, W17B, W21B, W22B, W23B, and W24B. Further, the printed circuit board 400B is a multilayer substrate, and is provided with a plurality of through-holes including through-holes TH1B, TH2B, TH11B, and TH12B.

The wirings W1B, W2B, W3B, W4B, W5B, W6B, and W7B are coupled to the pads P1B, P2B, P3B, P4B, P5B, P6B, and P7B, respectively. Furthermore, the wirings W11B, W12B, W13B, W14B, W15B, W16B, and W17B are coupled to the pads P11B, P12B, P13B, P14B, P15B, P16B, and P17B, respectively. The wiring W7B is coupled to a wiring (not shown) provided on another layer through the through-hole TH2B. The wiring W16B is coupled to a wiring (not shown) provided on another layer through the through-hole TH11B. The wiring W17B is coupled to a wiring (not shown) provided on another layer through the through-hole TH12B.

The wiring W21B is coupled to the pads P1B and P4B. The wiring W22B is coupled to the pads P4B and P11B. The wiring W23B is coupled to the pads P11B and P14B. The wiring W24B is coupled to the pad P4B, and is further coupled to a ground pattern (not shown) provided on another layer through the through-hole TH1B. Therefore, the wirings W1B, W4B, W11B, W14B, W21B, W22B, W23B, and W24B are at the ground potential.

The wiring W5B extends from the pad P5B in the y direction. The wiring W1B extends from the pad P1B in the y direction through a space between the pad P5B and the pad P3B. The wiring W4B extends from the pad P4B in the y direction through a space between the pad P3B and the pad P15B. The wiring W2B extends from the pad P2B in the y direction through a space between the wiring W1B and the wiring W3B. The wiring W3B extends from the pad P3B in the y direction through a space between the wiring W2B and the wiring W4B. That is, the wirings W2B and W3B are positioned between the wirings W1B and W4B that are at the ground potential. Therefore, crosstalk between signals propagating through the wirings W2B and W3B and signals propagating through the wirings W5B and W15B in the x direction is reduced by the wirings W1B and W4B that are at the ground potential. For this reason, the signals propagating through the wirings W2B and W3B are protected from noise caused by the signals propagating through the wirings W5B and W15B, and the signals propagating through the wirings W5B and W15B are protected from noise caused by the signals propagating through the wirings W2B and W3B.

Further, since the wiring W21B at the ground potential is provided between the wirings W2B and W3B and the wiring W6B, crosstalk between the signals propagating through the wirings W2B and W3B and the signal propagating through the wiring W6B in the y direction is reduced by the wiring W21B that is at the ground potential. For this reason, the signals propagating through the wirings W2B and W3B are protected from noise caused by the signal propagating through the wiring W6B, and the signal propagating through the wiring W6B is protected from noise caused by the signals propagating through the wirings W2B and W3B.

As described above, the wirings W2B, W3B, W5B, W6B, and W15B are guarded from noise by the wirings W1B, W4B, and W21B that are at the ground potential. Therefore, a possibility that the semiconductor device 100 malfunctions due to an unnecessary pulse superimposed on any of these wirings is reduced.

The wiring W15B extends from the pad P15B in the y direction through a space between the wiring W4B and the wiring W11B. The wiring W11B extends from the pad P11B in the y direction through a space between the pad P15B and the pad P13B. The wiring W14B extends from the pad P14B in the y direction. The wiring W12B extends from the pad P12B in the y direction through a space between the wiring W11B and the wiring W13B. The wiring W13B extends from the pad P13B in the y direction through a space between the wiring W12B and the wiring W14B. That is, the wirings W12B and W13B are positioned between the wirings W11B and W14B that are at the ground potential. Therefore, crosstalk between signals propagating through the wirings W12B and W13B and a signal propagating through the wiring W15B in the x direction is reduced by the wirings W11B and W14B that are at the ground potential. For this reason, the signals propagating through the wirings W12B and W13B are protected from noise caused by the signal propagating through the wiring W15B, and the signal propagating through the wiring W15B is protected from noise caused by the signals propagating through the wirings W12B and W13B.

Further, since the wiring W23B at the ground potential is provided between the wirings W12B and W13B and the wiring W16B, crosstalk between signal propagating through the wirings W12B and W13B and a signal propagating through the wiring W16B in the y direction is reduced by the wiring W23B that is at the ground potential. For this reason, the signals propagating through the wirings W12B and W13B are protected from noise caused by the signal propagating through the wiring W16B, and the signal propagating through the wiring W16B is protected from noise caused by the signals propagating through the wirings W12B and W13B.

As described above, the wirings W12B, W13B, W15B, and W16B are guarded from noise by the wirings W11B, W14B, and W23B that are at the ground potential. Therefore, a possibility that the semiconductor device 100 malfunctions due to an unnecessary pulse superimposed on any of these wirings is reduced.

In the present embodiment, the integrated circuit chip 200 of the semiconductor device 100 is mounted on either the printed circuit board 400A or the printed circuit board 400B. The integrated circuit chip 200 operates in a mode A when the semiconductor device 100 is mounted on the printed circuit board 400A, and operates in a mode B when the semiconductor device 100 is mounted on the printed circuit board 400B. The control section 210 determines whether the printed circuit board 400 on which the semiconductor device 100 is mounted is the printed circuit board 400A or the printed circuit board 400B, based on, for example, the potential of the terminal S1 of the semiconductor device 100, that is, the potential of the terminal T1 of the integrated circuit chip 200. For example, when the potential of the terminal T1 is a low level, the control section 210 determines that the printed circuit board 400 is the printed circuit board 400A and operates in the mode A. When the potential of the terminal T1 is a high level, the control section 210 determines that the printed circuit board 400 is the printed circuit board 400B and operates in the mode B.

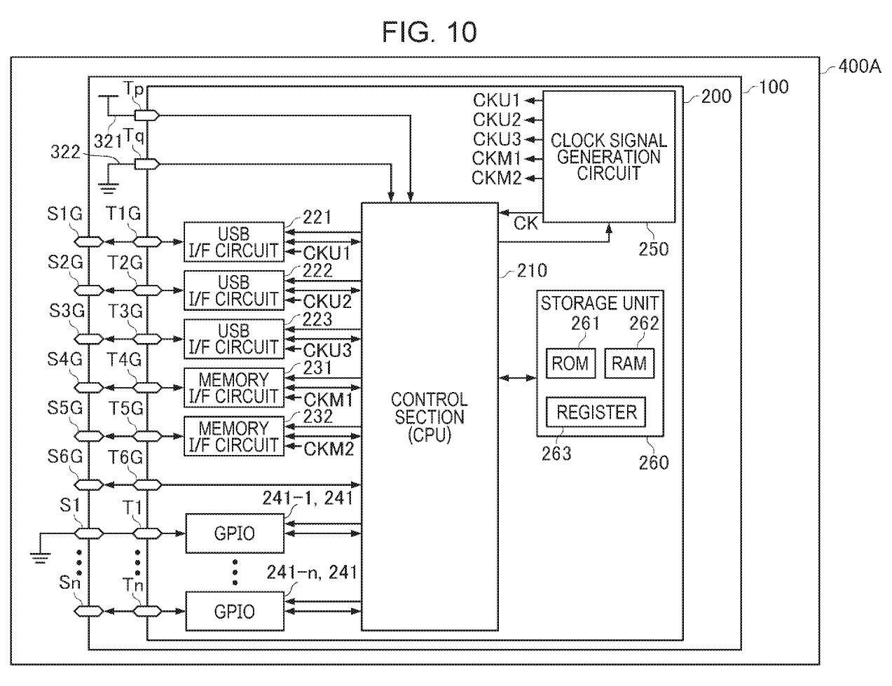

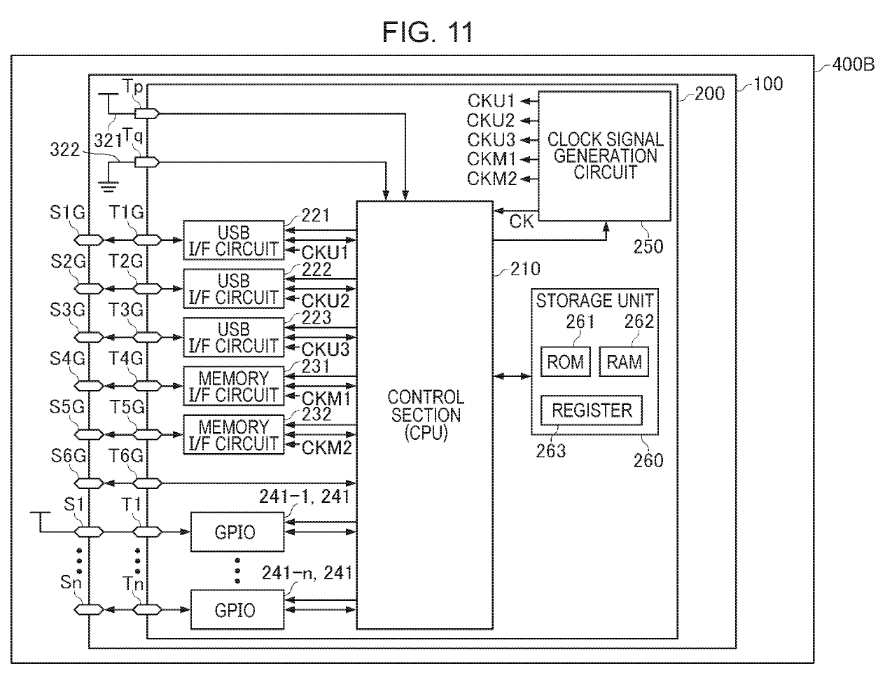

In the present embodiment, the wiring W7A provided on the printed circuit board 400A is at the ground potential, and the wiring W7B provided on the printed circuit board 400B is at the power supply potential. Further, the pad P7A is coupled to the terminal S1 of the semiconductor device 100 when the semiconductor device 100 is mounted on the printed circuit board 400A, and the pad P7B is coupled to the terminal S1 of the semiconductor device 100 when the semiconductor device 100 is mounted on the printed circuit board 400B. Therefore, when the semiconductor device 100 is mounted on the printed circuit board 400A, the pad P7A and the terminal S1 of the semiconductor device 100 are coupled to each other and the potential of the terminal T1 of the integrated circuit chip 200 is at the ground potential as shown in FIG. 10. On the other hand, when the semiconductor device 100 is mounted on the printed circuit board 400B, the pad P7B and the terminal S1 of the semiconductor device 100 are coupled to each other and the potential of the terminal T1 of the integrated circuit chip 200 is at the power supply potential as shown in FIG. 11. Therefore, when the potential of the terminal T1 is a low level, the control section 210 determines that the printed circuit board 400 on which the semiconductor device 100 is mounted is the printed circuit board 400A and can operate in the mode A. When the potential of the terminal T1 is a high level, the control section 210 determines that the printed circuit board 400 is the printed circuit board 400B and can operate in the mode B.

For example, when the semiconductor device 100 is mounted on the printed circuit board 400A, the pads P1A, P2A, P3A, and P4A are coupled to predetermined terminals Sa, Sb, Sc, and Sd of the semiconductor device 100, respectively. When the semiconductor device 100 is mounted on the printed circuit board 400B, the pads P1B, P2B, P3B, and P4B are coupled to the terminals Sa, Sb, Sc, and Sd of the semiconductor device 100, respectively. For example, signals propagating to the terminals Sa, Sb, Sc, and Sd of the semiconductor device 100 are different in the mode A and the mode B.

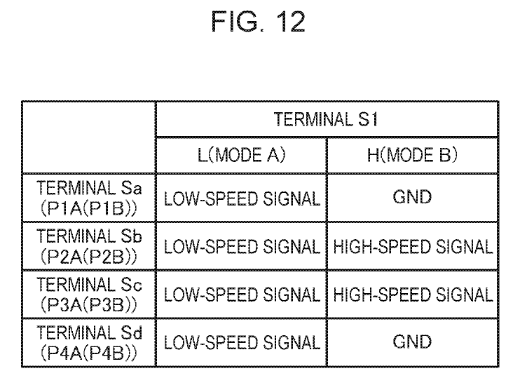

FIG. 12 is a diagram showing an example of a correspondence relationship between the modes A and B and the signals propagating to the terminals Sa, Sb, Sc, and Sd. In the example shown in FIG. 12, a low-speed signal propagates to each of the terminals Sa, Sb, Sc, and Sd in the mode A. That is, a low-speed signal propagates to each of the wiring W1A, W2A, W3A, and W4A provided on the printed circuit board 400A. As described above, when the control section 210 determines that the printed circuit board 400 on which the semiconductor device 100 is mounted is the printed circuit board 400A, the control section 210 sets the terminals Sa, Sb, Sc, and Sd to terminals to which the low-speed signals propagate. The low-speed signal has a frequency of less than 20 MHz. For example, the low-speed signal may be a CMOS signal of 3.3 V or the like.

On the other hand, in the mode B, the high-speed signal propagates to each of the terminals Sb and Sc and the terminals Sa and Sd are coupled to the wirings W1A and W4A and are thus at the ground potential. That is, the high-speed signal propagates to each of the wirings W2A and W3A provided on the printed circuit board 400A, and the wirings W2A and W3A are guarded from noise by the wirings W1B, W4B, and W21B that are at the ground potential. As described above, when the control section 210 determines that the printed circuit board 400 on which the semiconductor device 100 is mounted is the printed circuit board 400B, the control section 210 sets the terminals Sb and Sc to terminals to which the high-speed signals propagate. The high-speed signal has a frequency of 20 MHz or higher.

For example, the high-speed signal may be a USB communication signal for a high-speed mode (480 MHz) of USB 2.0. For example, a signal for allowing the semiconductor device 100 to communicate with the PC 2, the SD control IC 170, the wireless LAN module, and the like is the USB communication signal. Further, the high-speed signal in the present application may be a high-speed differential signal in which two signals form a set.

Furthermore, the high-speed signal may be an LVDS signal. For example, print data output from the semiconductor device 100 to the head drive IC 120, scan data input from the scanner module 63 to the semiconductor device 100, image data output from the semiconductor device 100 to the LCD control IC 160, or the like may be the LVDS signal. In the electronic apparatus 1 in which the printed circuit board 400B is mounted, the size of the LCD 65 is large and an animation is displayed on the LCD 65. Accordingly, the control section 210 operates in the mode B and transmits image data of the high-speed signals to the LCD control IC 160 via the terminal group S6G. On the other hand, in the electronic apparatus 1 in which the printed circuit board 400A is mounted, the size of the LCD 65 is small and an animation is not displayed on the LCD 65. Accordingly, the control section 210 operates in the mode A and transmits image data of the low-speed signals to the LCD control IC 160 via the terminal group S6G.

In addition, for example, it is assumed that the pads P11A, P12A, P13A, and P14A are respectively coupled to predetermined terminals Se, Sf, Sg, and Sh of the semiconductor device 100 when the semiconductor device 100 is mounted on the printed circuit board 400A and that the pads P11B, P12B, P13B, and P14B are respectively coupled to the terminals Se, Sf, Sg, and Sh of the semiconductor device 100 when the semiconductor device 100 is mounted on the printed circuit board 400B, signals propagating to the terminals Se, Sf, Sg, and Sh of the semiconductor device 100 are different in the mode A and the mode B, for example.

Although not shown, in the mode A, the low-speed signal propagates to each of the terminals Se, Sf, Sg, and Sh, and the low-speed signal propagates to each of the wiring W11A, W12A, W13A, and W14A provided on the printed circuit board 400A. As described above, when the control section 210 determines that the printed circuit board 400 on which the semiconductor device 100 is mounted is the printed circuit board 400A, the control section 210 sets the terminals Se, Sf, Sg, and Sh to terminals to which the low-speed signals propagate.

On the other hand, in the mode B, the high-speed signal propagates to each of the terminals Sf and Sg and the terminals Se and Sh are coupled to the wirings W11A and W14A and are thus at the ground potential. That is, the high-speed signal propagates to each of the wirings W12A and W13A provided on the printed circuit board 400A, and the wirings W12A and W13A are guarded from noise by the wirings W11B, W14B, and W23B that are at the ground potential. As described above, when the control section 210 determines that the printed circuit board 400 on which the semiconductor device 100 is mounted is the printed circuit board 400B, the control section 210 sets the terminals Sb and Sc to terminals to which the high-speed signals propagate.

The terminal Tp of the integrated circuit chip 200 is an example of a "first terminal", and the wiring 321 of the base substrate 300 is an example of a "first wiring". The terminal Tq of the integrated circuit chip 200 is an example of a "second terminal", and the wiring 322 of the base substrate 300 is an example of a "second wiring". Further, the predetermined terminal Ti of the integrated circuit chip 200 is an example of a "third terminal".

### 6. Operational Effect

As described above, according to the electronic apparatus 1 of the present embodiment, in the semiconductor device 100, one integrated circuit chip 200 can be mounted in a plurality of types of packages 330. Accordingly, it is not necessary to design and produce an integrated circuit chip having different functions for each type of package 330. For this reason, it is possible to minimize production cost and production man-hours by minimizing production lines and production apparatuses for the integrated circuit chip 200, and to further minimize management man-hours for the integrated circuit chip 200. Therefore, a reduction in cost can be achieved. Further, since it is possible to mount the integrated circuit chip 200 in the package 330 having the minimum required size according to the functions of the integrated circuit chip 200 by limiting the functions of the integrated circuit chip 200 according to the functions of the electronic apparatus 1, a reduction in the size of the semiconductor device 100 is achieved. Furthermore, since the integrated circuit chip 200 can be mounted in the package 330 having the minimum required size according to the functions of the integrated circuit chip 200, the amount of materials required for the production of the package 330 can be reduced and production facilities for the integrated circuit chip 200 can be minimized. Therefore, resources, such as materials and personnel required for production, can be used without waste. In addition, since production facilities for the integrated circuit chip 200 can be minimized, the amount of compressed air and the amount of electricity to be used in the production plant can be reduced and the amount of CO₂ to be generated can be reduced.

Further, according to the electronic apparatus 1 of the present embodiment, in the semiconductor device 100, the terminal Ti is also used as the CMOS terminal or the LVDS terminal when the integrated circuit chip 200 is mounted in the package 330b. Therefore, the number of terminals of the integrated circuit chip 200 and the number of wirings of the printed circuit board 400 on which the semiconductor device 100 is mounted can be reduced. Furthermore, as the terminal Ti is dedicated as the CMOS terminal or the LVDS terminal and the functions of the integrated circuit chip 200 are limited, the integrated circuit chip 200 can be mounted in the package 330 having the minimum required size according to the functions of the integrated circuit chip 200.

In addition, when the functions of the integrated circuit chip 200 are limited according to the functions of the electronic apparatus 1 in which the semiconductor device 100 is mounted, the potentials of unused terminals of the integrated circuit chip 200 are fixed to a low level, so that a possibility that the potentials of the unused terminals become an intermediate potential is reduced. As a result, a possibility that the electronic apparatus 1 malfunctions is reduced.

Further, according to the electronic apparatus 1 of the present embodiment, the supply of unnecessary clock signals and unnecessary power to unused functional circuits is stopped in the integrated circuit chip 200. Accordingly, power consumption is reduced and power saving is achieved. Furthermore, according to the electronic apparatus 1 of the present embodiment, initial settings for unused functional circuits are not performed in the integrated circuit chip 200. Accordingly, power consumption required for the unnecessary initial settings is reduced and a startup time is also shortened, so that power saving is achieved. Moreover, according to the electronic apparatus 1 of the present embodiment, the frequency of the clock signal is changed according to the package 330 in which the integrated circuit chip 200 is mounted. Accordingly, the performance of the integrated circuit chip 200 can be improved within a range in which the inside of the package 330 does not reach an excessive temperature. For this reason, stable energy consumption is achieved at low cost, which contributes to a reduction in the amount of power to be generated in the power plant and is also environmentally friendly.

Further, according to the electronic apparatus 1 of the present embodiment, the functions of the terminals Sa, Sb, Sc, and Sd of the semiconductor device 100 and the functions of the terminals Se, Sf, Sg, and Sh of the semiconductor device 100 are switched according to the printed circuit board 400 on which the semiconductor device 100 is mounted. Therefore, the number of necessary terminals and the number of necessary wirings can be minimized since these terminals are used for multiple purposes. As a result, a reduction in the size of the semiconductor device 100 is achieved. Furthermore, since production lines and production apparatuses for the semiconductor device 100 can also be minimized, production cost of the semiconductor device 100 is reduced. As a result, a reduction in cost is achieved. In addition, when the semiconductor device 100 is mounted on the printed circuit board 400B, wirings to which the high-speed signal propagates are sandwiched between ground wirings. Accordingly, crosstalk due to the high-speed signal is reduced, so that the possibility of malfunction is reduced. Further, according to the electronic apparatus 1 of the present embodiment, the terminals of the semiconductor device 100 are used for multiple purposes, so that the number of necessary terminals and the number of necessary wirings can be minimized. Therefore, the amount of materials required for the production of the semiconductor device 100 and the printed circuit board 400 can be reduced and production facilities for the semiconductor device 100 and the printed circuit board 400 can be minimized. As a result, resources, such as materials and personnel required for production, can be used without waste. Furthermore, since production facilities for the semiconductor device 100 and the printed circuit board 400 can be minimized, the amount of compressed air and the amount of electricity to be used in the production plant can be reduced and the amount of CO₂ to be generated can be reduced.

Moreover, according to the electronic apparatus 1 of the present embodiment, the printed circuit board 400 on which the semiconductor device 100 is mounted can be determined based on the potential of the terminal S1 of the semiconductor device 100. Therefore, a reduction in the size and cost of the semiconductor device 100 can be achieved.

As described above, according to the electronic apparatus 1 of the present embodiment, it is possible to contribute to Goals 7, 8, 9, 11, and 12 of SDGs.

The present disclosure is not limited to the present embodiment, and various modifications may be made without departing from the scope of the present disclosure.

For example, the package 330 of the semiconductor device 100 has been described as a ball grid array (BGA) in the present embodiment, but the package 330 may be a surface-mount package other than BGAs, such as a system in package (SiP), a land grid array (LGA), and a wafer process package (WPP). For example, when the package 330 is an LGA, terminals of the semiconductor device 100 are lands provided on the package 330, and the lands, which are the terminals of the semiconductor device 100, and the pads 410 provided on the printed circuit board 400 are coupled to each other by the solder balls 310.

The embodiments have been described above. However, the present disclosure is not limited to the embodiments, and can be carried out in various aspects without departing from the scope of the present disclosure. For example, the embodiments described above can also be combined with each other as appropriate.

The present disclosure includes substantially the same configurations as the configurations described in the embodiments, for example, configurations having the same function, method, and result, or configurations having the same object and effects. Further, the present disclosure includes configurations in which non-essential parts of the configurations described in the embodiments are replaced. Furthermore, the present disclosure includes configurations that achieve the same operational effects as the configurations described in the embodiments or configurations that can achieve the same objects as the configurations described in the embodiments. In addition, the present disclosure includes configurations in which known technologies are added to the configurations described in the embodiments.

The following contents are derived from the above-described embodiments.

According to an aspect of the present disclosure, there is provided a semiconductor device including a package, and an integrated circuit chip that is mounted on an internal substrate of the package, in which the integrated circuit chip includes a plurality of terminals, a control section, and a plurality of functional circuits, the internal substrate is provided with a first wiring that is coupled to a first terminal among the plurality of terminals and a second wiring that is coupled to a second terminal among the plurality of terminals, and the control section determines a type of the package based on a potential of the first terminal and a potential of the second terminal, and controls operations of the plurality of functional circuits according to the type of the package.

According to the semiconductor device, one integrated circuit chip can be mounted in a plurality of types of packages. Accordingly, it is not necessary to design and produce an integrated circuit chip having different functions for each type of package. For this reason, it is possible to minimize production cost and production man-hours by minimizing production lines and production apparatuses for the integrated circuit chip, and to further minimize management man-hours for the integrated circuit chip. Therefore, a reduction in cost can be achieved. Further, according to the semiconductor device, it is possible to mount the integrated circuit chip in the package having the minimum required size according to the functions of the integrated circuit chip by limiting the functions of the integrated circuit chip according to the functions of an electronic apparatus to be mounted. Therefore, a reduction in the size of the semiconductor device is achieved. Furthermore, according to the semiconductor device, the integrated circuit chip can be mounted in the package having the minimum required size according to the functions of the integrated circuit chip. Accordingly, the amount of materials required for the production of the package can be reduced and production facilities for the integrated circuit chip can be minimized. Therefore, resources, such as materials and personnel required for production, can be used without waste. In addition, according to the semiconductor device, production facilities for the integrated circuit chip can be minimized. Accordingly, the amount of compressed air and the amount of electricity to be used in the production plant can be reduced and the amount of CO₂ to be generated can be reduced. Therefore, according to the semiconductor device, it is possible to contribute to Goals 7, 8, 9, 11, and 12 of SDGs.

In the semiconductor device according to the aspect, the control section may determine whether a third terminal among the plurality of terminals is also used as a CMOS terminal or an LVDS terminal according to the type of the package.

According to the semiconductor device, the number of the terminals of the integrated circuit chip and the number of wirings of a printed circuit board on which the semiconductor device is mounted can be reduced. Further, according to the semiconductor device, as the functions of the integrated circuit chip are limited according to the functions of the electronic apparatus to be mounted, the integrated circuit chip can be mounted in the package having the minimum required size according to the functions of the integrated circuit chip. Therefore, according to the semiconductor device, it is possible to contribute to Goals 7, 8, 9, 11, and 12 of SDGs.

In the semiconductor device according to the aspect, the control section may fix a potential of an unused terminal among the plurality of terminals to a low level according to the type of the package.

According to the semiconductor device, a possibility that the potential of the terminal not used when the functions of the integrated circuit chip are limited according to the functions of an electronic apparatus to be mounted becomes an intermediate potential is reduced. As a result, a possibility that the electronic apparatus in which the semiconductor device is mounted malfunctions is reduced. Therefore, according to the semiconductor device, it is possible to contribute to Goals 7, 8, 9, 11, and 12 of SDGs.

In the semiconductor device according to the aspect, the control section may stop supplying a clock signal to an unused functional circuit among the plurality of functional circuits according to the type of the package.

According to the semiconductor device, since the supply of an unnecessary clock signal is stopped, power consumption is reduced and power saving is achieved. For this reason, stable energy consumption is achieved at low cost, which contributes to a reduction in the amount of power to be generated in the power plant and is also environmentally friendly. Therefore, according to the semiconductor device, it is possible to contribute to Goals 7, 8, 9, 11, and 12 of SDGs.

In the semiconductor device according to the aspect, the control section may stop supplying power to an unused functional circuit among the plurality of functional circuits according to the type of the package.

According to the semiconductor device, since the supply of unnecessary power is stopped, power consumption is reduced and power saving is achieved. For this reason, stable energy consumption is achieved at low cost, which contributes to a reduction in the amount of power to be generated in the power plant and is also environmentally friendly. Therefore, according to the semiconductor device, it is possible to contribute to Goals 7, 8, 9, 11, and 12 of SDGs.

In the semiconductor device according to the aspect, the control section may not perform an initial setting for an unused functional circuit among the plurality of functional circuits according to the type of the package.

According to the semiconductor device, power consumption required for the unnecessary initial settings is reduced and a startup time is also shortened, so that power saving is achieved. For this reason, stable energy consumption is achieved at low cost, which contributes to a reduction in the amount of power to be generated in the power plant and is also environmentally friendly. Therefore, according to the semiconductor device, it is possible to contribute to Goals 7, 8, 9, 11, and 12 of SDGs.

In the semiconductor device according to the aspect, the control section may change a frequency of a clock signal according to the package.

According to the semiconductor device, performance can be improved within a range in which the inside of the package does not reach an excessive temperature, according to the type of the package. For this reason, stable energy consumption is achieved at low cost, which contributes to a reduction in the amount of power to be generated in the power plant and is also environmentally friendly. Therefore, according to the semiconductor device, it is possible to contribute to Goals 7, 8, 9, 11, and 12 of SDGs.

What is claimed is:

1. A semiconductor device comprising:
a package; and
an integrated circuit chip that is mounted on an internal substrate of the package, wherein
the integrated circuit chip includes a plurality of terminals, a control section, and a plurality of functional circuits,
the internal substrate is provided with a first wiring that is coupled to a first terminal among the plurality of terminals and a second wiring that is coupled to a second terminal among the plurality of terminals, and
the control section determines a type of the package based on a potential of the first terminal and a potential of the second terminal, and controls operations of the plurality of functional circuits according to the type of the package.

2. The semiconductor device according to claim 1, wherein
the control section determines whether a third terminal among the plurality of terminals is also used as a CMOS terminal or an LVDS terminal according to the type of the package.

3. The semiconductor device according to claim 1, wherein
the control section fixes a potential of an unused terminal among the plurality of terminals to a low level according to the type of the package.

4. The semiconductor device according to claim 1, wherein
the control section stops supplying a clock signal to an unused functional circuit among the plurality of functional circuits according to the type of the package.

5. The semiconductor device according to claim 1, wherein
the control section stops supplying power to an unused functional circuit among the plurality of functional circuits according to the type of the package.

6. The semiconductor device according to claim 1, wherein
the control section does not perform an initial setting for an unused functional circuit among the plurality of functional circuits according to the type of the package.

7. The semiconductor device according to claim 1, wherein
the control section changes a frequency of a clock signal according to the package.
